(19) United States
(12) Patent Application Publication
(10) Pub. No.: US 2019/0139823 A1
(43) Pub. Date: May 9, 2019

(54) METHODS OF FORMING CONDUCTIVE LINES AND VIAS AND THE RESULTING STRUCTURES

(71) Applicant: GLOBALFOUNDRIES Inc., Grand Cayman (KY)

(72) Inventors: Hsueh-Chung Chen, Cohoes, NY (US); Jason E. Stephens, Menands, NY (US); Lars W. Liebmann, Mechanicville, NY (US); Guillaume Bouche, Albany, NY (US)

(21) Appl. No.: 15/804,006

(22) Filed: Nov. 6, 2017

(51) Int. Cl. H01L 21/768; H01L 23/528; H01L 23/522; H01L 21/3213

(52) U.S. Cl. CPC H01L 21/76883; H01L 23/528; H01L 21/32139; H01L 21/76802; H01L 21/76877; H01L 23/5226

(57) ABSTRACT

One illustrative method disclosed herein may include forming first and second via openings and forming conductive material for first and second conductive vias across substantially an entirety of an upper surface of a layer of insulating material and in the via openings. A patterned line etch mask layer is then formed above the conductive material, the etch mask having a first feature corresponding to a first conductive line and a second feature corresponding to a second conductive line, and performing at least one etching process to define the first and second conductive lines that are arranged in a tip-to-tip configuration. In this example, a first edge of the first conductive via is substantially aligned with a first end of the first conductive line and a second edge of the second conductive via is substantially aligned with a second end of the second conductive line.

### BACKGROUND OF THE INVENTION

### 1. Field of the Invention

The present disclosure generally relates to the fabrication of semiconductor devices, and, more particularly, to various novel methods of forming conductive lines and vias on integrated circuit (IC) products and the resulting novel structures.

### 2. Description of the Related Art

Modern integrated (IC) products include a very large number of active and passive semiconductor devices (i.e., circuit elements) that are formed on a very small area of a semiconductor substrate or chip. Active semiconductor devices include, for example, various types of transistors, e.g., field effect transistors (FETs), bi-polar transistors, etc. Examples of passive semiconductor devices include capacitors, resistors, etc. These semiconductor devices are arranged in various circuits that are part of various functional components of the IC product, e.g., a microprocessor (logic area), a memory array (memory area), an ASIC, etc. Like all electronic devices, semiconductor devices in an IC product need to be electrically connected through wiring so that they may operate as designed. In an IC product, such wiring is done through multiple metallization layers formed above a semiconductor substrate.

Typically, due to the large number of semiconductor devices (i.e., circuit elements) and the required complex layout of modern integrated circuits, the electrical connections or “wiring arrangement” for the individual semiconductor devices cannot be established within the same device level on which the semiconductor devices are manufactured. Accordingly, the various electrical connections that constitute the overall wiring pattern for the IC product are formed in a metallization system that comprises one or more additional stacked so-called “metallization layers” that are formed above the device level of the product. These metallization layers are typically comprised of a plurality of conductive metal lines formed in a layer of insulating material. Conductive vias are formed in insulating material between the layers of conductive metal lines. Generally, the conductive lines provide the intra-level electrical connections, while the conductive vias provide the inter-level connections or vertical connections between different levels of the conductive lines. These conductive lines and conductive vias may be comprised of a variety of different materials, e.g., copper, cobalt, ruthenium, iridium, tungsten, aluminum, etc. (with appropriate barrier layers). The first metallization layer in an integrated circuit product is typically referred to as the “M1” layer. Normally, a plurality of conductive vias (typically referred to as “V0” vias) are used to establish electrical connection between the M1 layer and lower level conductive structures—so called device-level contacts (explained more fully below). In some more advanced devices, another metallization layer comprised of conductive lines (sometimes called the “M0” layer) is formed between the device level contacts and the V0 vias.

FIG. 1 is a cross-sectional view of an illustrative IC product 10 comprised of a transistor device 11 formed in and above a semiconductor substrate 12. Also depicted are a plurality of conductive vias 14 (which are sometimes referred to as “CA contact” structures) for establishing electrical connection to the simplistically depicted source/drain regions 20 of the device 11, and another conductive via 16 (which is sometimes referred to as a “CB contact” structure). As shown in FIG. 1, the via 16 is typically positioned vertically above isolation material 13 that surrounds the device 11, i.e., the via 16 is typically not positioned above the active region defined in the substrate 12, but it may be in some advanced architectures.

The transistor 11 comprises an illustrative gate structure 22, i.e., a gate insulation layer 22A and a gate electrode 22B, a gate cap 24, a sidewall spacer 26 and simplistically depicted source/drain regions 20. As noted above, the isolation region 13 has also been formed in the substrate 12 at this point in the process flow. At the point of fabrication depicted in FIG. 1, layers of insulating material 30A, 30B, i.e., interlayer dielectric materials, have been formed above the substrate 12. Other layers of material, such as contact etch stop layers and the like, are not depicted in the drawing. Also depicted are illustrative raised epi source/drain regions 32 and source/drain contact structures 34 which typically include a so-called “trench silicide” (TS) structure 36. The vias 14 may be in the form of discrete contact elements, i.e., one or more individual contact plugs having a generally square-like shape or cylindrical shape when viewed from above, that are formed in an interlayer dielectric material. In other applications, vias 14 may also be a line-type features that contact underlying line-type features, e.g., the TS structure 36 that contacts the source/drain region 20, and typically extends across the entire active region on the source/drain region 20 in a direction that is parallel to the gate width direction of the transistor 11, i.e., into and out of the plane of the drawing in FIG. 1. The vias 14 (the CA contacts) and the via 16 (the CB contact) are all considered to be device-level contacts within the industry.

FIG. 1 depicts an illustrative example of an IC product 10 that includes a so-called M0 metallization layer of the multi-level metallization system for the product 10. The M0 metallization layer is formed in a layer of insulating material 46, e.g., a low-k insulating material, and it is formed to establish electrical connection to the device-level contacts—the vias 14 and the via 16. Also depicted in FIG. 1 is the so-called M1 metallization layer for the product 10 that is formed in a layer of insulating material 38, e.g., a low-k insulating material. A plurality of conductive vias—so-called V0 vias 40—is provided to establish electrical connection between the M0 metallization layer and the M1 metallization layer. Both the M0 metallization layer and the M1 metallization layer typically include a plurality of metal lines 44, 42 (respectively) that are routed as needed across the product 10. The formation of the M0 metallization layer may be helpful in reducing the overall resistance of the circuits formed on the substrate 12. However, in some IC products, the M0 metallization layer may be omitted and the V0 vias 40 of the M1 metallization layer make contact with the CA contacts 14 and the CB contact 16. A modern advanced IC product may include 5-12 metallization layers, e.g., device layers, M1/VO, M2/V1, M3/V2, etc. It should be noted that, in FIG. 1, the M0 lines 44 are illustrated as running parallel to the gates while the M1 lines 42 are shown running perpendicular to gates. The opposite is also a possibility as further shown on FIG. 2.

The various transistor devices that are formed for an IC product must be electrically isolated from one another to properly function in an electrical circuit. Typically, this is accomplished by forming a trench in the substrate 12, and filling the trench with an insulating material, such as silicon dioxide. Within the industry, these isolation regions may sometimes be referred to as “diffusion breaks.” FIG. 2 is a simplistic plan view of a portion of the IC product 10 wherein an illustrative single diffusion break (SDB) structure 50 separates two illustrative circuit structures 52 and 54 of the IC product from one another along the line 56. In one example, the section 52 may be a NAND2 circuit structure, while the section 54 may be a MUX circuit structure. Also depicted in FIG. 2 are a plurality of transistor structures comprised of a gate cap 24 and trench silicide regions 36 in the source/drain regions of the transistor devices. Various M0 metal lines 44 are depicted in FIG. 2 as well.

As shown in the circled region 70, vias (CA contact structures) 14 (shown in dashed lines) have been formed to establish electrical connection to the source/drain regions of transistors on opposite sides of the SDB 50. To make the connection between the metal lines 44 and the underlying CA contact structures 14, there must be a tip-to-tip spacing 72 between the ends of the respective M0 metal lines 44. This is typically accomplished by performing lithography and etching processes to define separated trenches in a layer of insulating material (not shown) for the respective lines 44 and thereafter forming both the vias (CA contact structures) 14 and the metal lines 44 in the trenches at the same time using a damascene processing technique. Another typical requirement when making such connections is that the ends of the metal lines 44 need to overlap the vias (CA contact structures) 14 by a distance 74 to insure that there is sufficient contact area between the metal line 44 and the vias (CA contact structures) 14 such that the resistance of the overall contacting arrangement is not increased relative to what is anticipated by the design process. In some situations, the vias (CA source/drain contact structures) 14 have to be contacted at a distance corresponding to the gate pitch of the gate structures of the various transistor devices to take advantage of the space savings achieved when an IC product includes a SDB isolation structure. The gate pitch of the transistors on modern IC products is currently very small and further reductions are anticipated as future products are developed. Unfortunately, directly patterning trenches for such metal lines 44 having such a tip-to-tip arrangement is very challenging given the very small dimensions of modern transistor devices, the increased packing densities of semiconductor devices on modern IC products and the very small and ever decreasing gate pitch of transistor devices on modern IC products. Also depicted in FIG. 2, in the circled region 80, is the formation of metal lines 44 that contact spaced-apart vias (CB gate contact structures) 16 that are formed to contact gate structures on different transistor devices.

FIG. 3 is an enlarged view of an embodiment wherein the M1 metallization layer 84 (M1/V0) was formed so as to establish electrical contact to a device level contact 80 that was previously formed in a layer of layer of insulating material 81. The metallization layer 84 comprises a V0 via 84A and an M1 metal line 84B. After the formation of the device level contact 80, an etch stop layer 85 and another layer of insulating material 82 were formed on the product. Next one or more etching processes were performed to define a trench 92 for the M1 metal line 84B and a via opening 90 for the V0 via 84A. The via opening 90 exposes the device level contact 80. FIG. 3 depicts an example wherein the via 84A is positioned very near the end 84X of the metal line 84B, i.e., the via 84A is a near-line-end via. The trench 92 and via opening 90 are typically formed such that the end 84X of the line 84B “encloses” or overlaps the via 84A by a distance 96, which may vary depending upon the application (e.g., 5-15 nm). Typically, the sidewalls 95 of the trench 92 are formed at a very steep angle, e.g., 85-89 degrees relative to the horizontal. Additionally, these steep sidewalls 95 are located on three sides of the end portion of the line 84B (the two other steep sidewalls are not depicted in FIG. 3 as they are positioned adjacent sidewalls of the line 84B that are located in front of and behind the plane of the drawing depicted in FIG. 3). The overall depth of the opening that must be filled is indicated by the dimension 97. When there is such a near-line-end via configuration, the formation of various barrier layers (and/or seed layers) and bulk conductive material for the metal line 84B and the via 84A can be very challenging given the steep sidewalls 95 and the relatively large aspect ratio of the opening to be filled that is driven by the maximum depth of the overall opening to be filled, i.e., the dimension 97. More specifically, if the barrier/seed layers are not properly formed, there is a very high likelihood of overall device failure and reduced product yields.

The present disclosure is directed to novel methods of forming conductive lines and vias on integrated circuit (IC) products and the resulting novel structures that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to novel methods of forming conductive lines and vias on integrated circuit (IC) products and the resulting novel structures. One illustrative method disclosed herein may include forming first and second via openings in a layer of insulating material and forming conductive material for first and second conductive vias in the first and second via openings and across substantially an entirety of an upper surface of the layer of insulating material. In this example, the method further includes forming a patterned line etch mask layer above the conductive material, the patterned line etch mask having a first feature corresponding to a first conductive line that will be conductively coupled to the first conductive via and a second feature corresponding to a second conductive line that will be conductively coupled to the second conductive via, and performing at least one etching process through the patterned line etch mask to etch the conductive material and form the first conductive line and the second conductive line, wherein the first and second conductive lines are arranged in a tip-to-tip configuration and wherein a first edge of the first conductive via is substantially aligned with a first end of the first conductive line and a second edge of the second conductive via is substantially aligned with a second end of the second conductive line.

One illustrative integrated circuit product disclosed herein may include first and second conductive vias positioned in a layer of insulating material, a first conductive line that is conductively coupled to the first conductive via and a second conductive line that is conductively coupled to the second conductive via. In this example, the first and second conductive lines are arranged in a tip-to-tip configuration and a first edge of the first conductive via is substantially aligned with a first end of the first conductive line and a second edge of the second conductive via is substantially aligned with a second end of the second conductive line.

### BRIEF DESCRIPTION OF THE DRAWINGS

The disclosure may be understood by reference to the following description taken in conjunction with the accompanying drawings, in which like reference numerals identify like elements, and in which:

FIGS. 1-3 depict various illustrative prior art arrangements of metallization layers for an integrated circuit product; and

FIGS. 4-12 depict various novel methods disclosed herein for forming conductive lines and vias on integrated circuit (IC) products and the resulting novel structures.

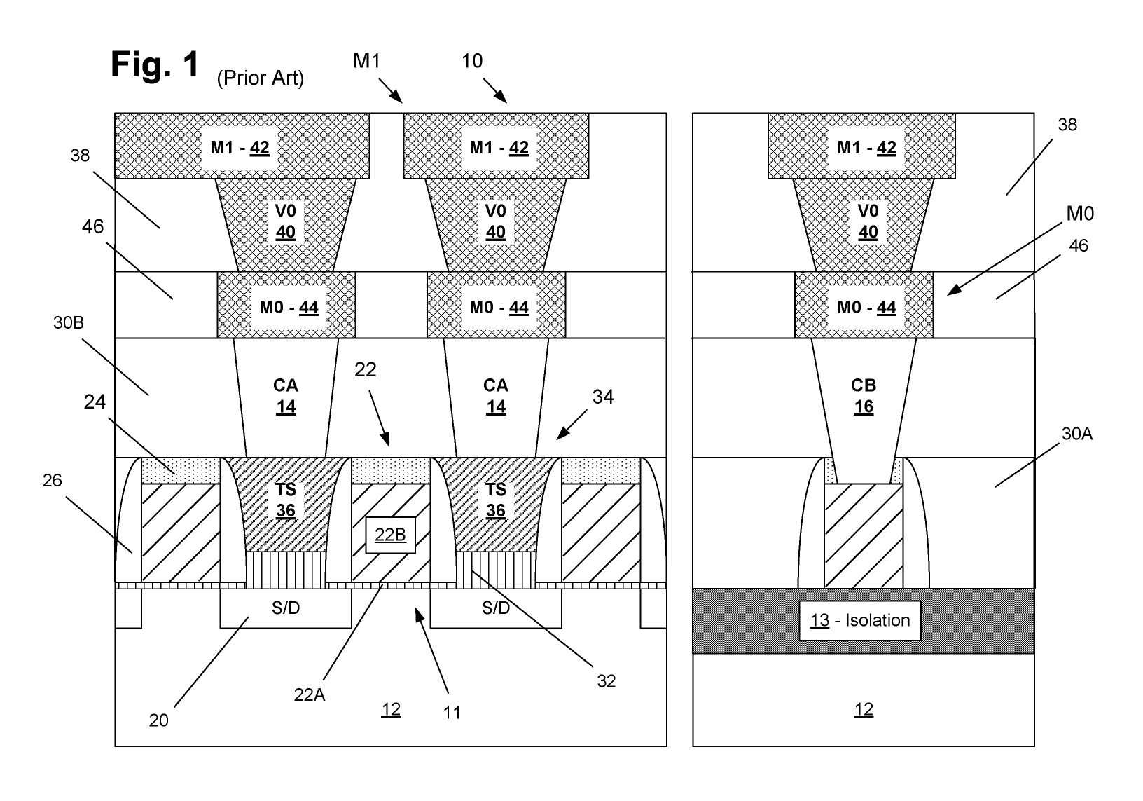

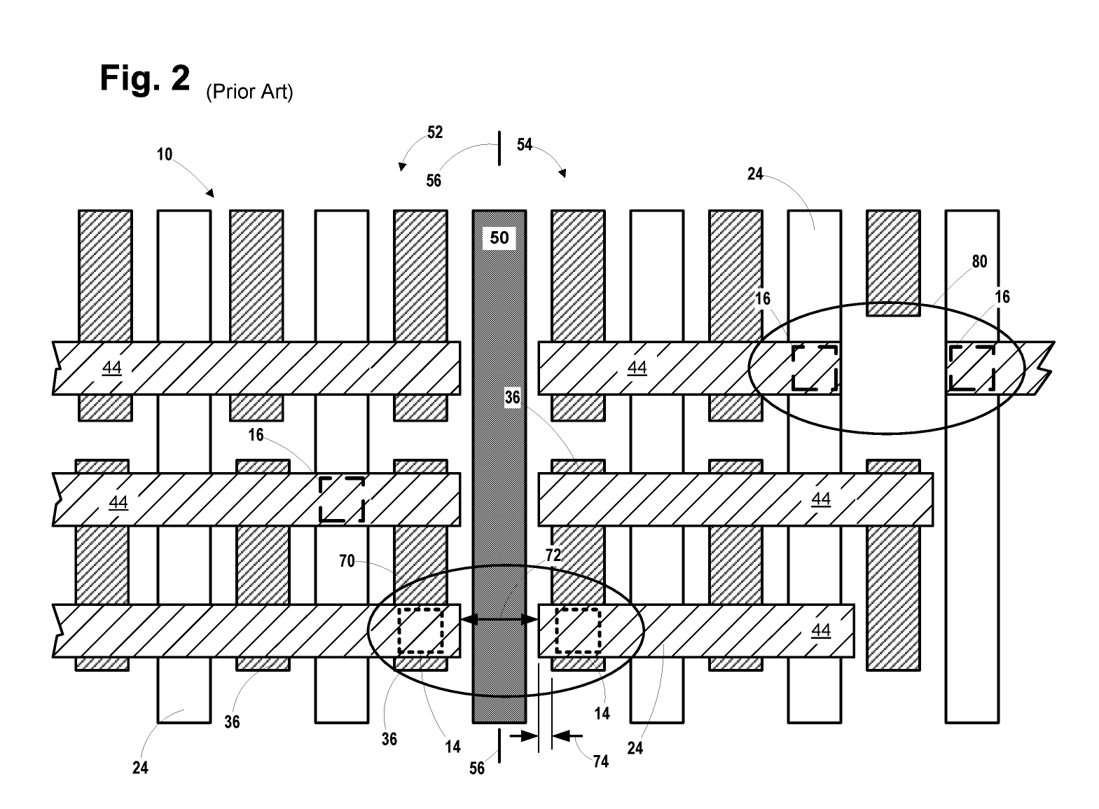

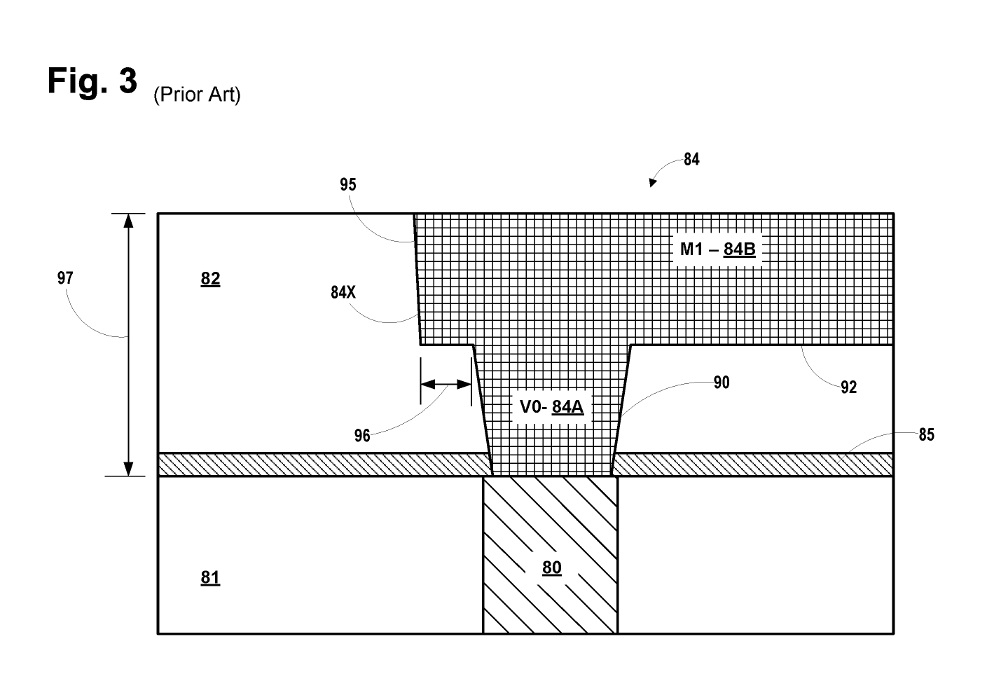

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various novel methods of forming conductive lines and vias on integrated circuit (IC) products and the resulting novel structures. The methods and devices disclosed herein may be employed at any level of a multiple-level metallization system of an IC product. The methods and devices disclosed herein may be employed in manufacturing IC products using a variety of technologies, e.g., NMOS, PMOS, CMOS, etc., and they may be employed in manufacturing a variety of different products, e.g., memory products, logic products, ASICs, etc. As will be appreciated by those skilled in the art after a complete reading of the present application, the methods and devices disclosed herein may be employed in forming integrated circuit products using transistor devices in a variety of different configurations, e.g., planar devices, FinFET devices, etc. The gate structures of the transistor devices may be formed using either “gate first” or “replacement gate” manufacturing techniques. Thus, the presently disclosed subject matter should not be considered to be limited to any particular form of transistors or the manner in which the gate structures of the transistor devices are formed. Of course, the inventions disclosed herein should not be considered to be limited to the illustrative examples depicted and described herein. With reference to the attached figures, various illustrative embodiments of the methods and devices disclosed herein will now be described in more detail.

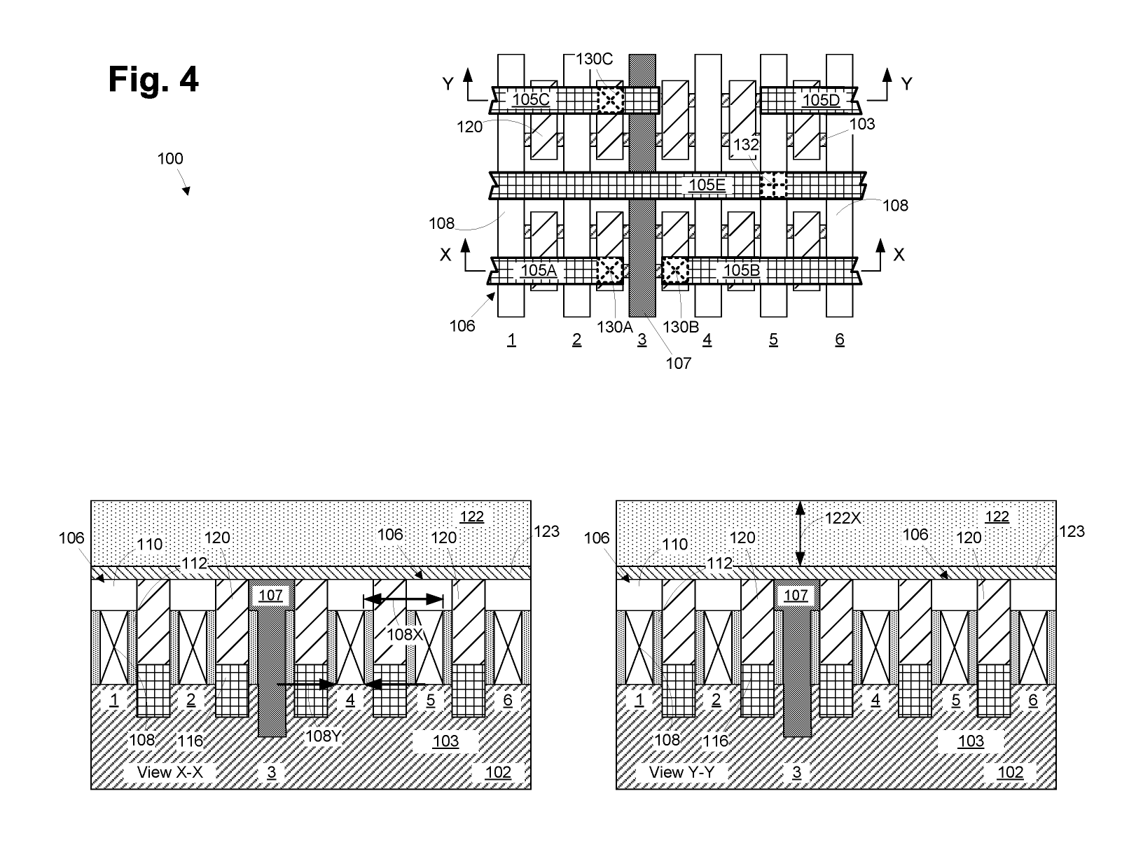

FIGS. 4-12 depict various novel methods of forming conductive lines and vias on an integrated circuit (IC) product 100 and the resulting novel structures. FIG. 4 includes a simplistic plan view of one illustrative embodiment of an IC product 100. The product 100 generally comprises a plurality of gates 106 (numbered 1-6 for ease of reference) for various transistor devices that are formed in and above a semiconductor substrate 102. In the illustrative example depicted herein, the transistor devices are FinFET devices, but the inventions disclosed herein should not be considered to be limited to IC products that include FinFET transistor devices. A plurality of fins 103 have been formed in the substrate 102 using traditional manufacturing techniques, and the gates 106 have been formed across the fins 103. Also depicted in the plan view are illustrative source/drain contact structures 120 (e.g., trench silicide structures) that are conductively coupled to the source/drain regions of the transistor devices. As depicted, a single diffusion break (SDB) 107 has been formed through gate number 3. The SDB 107 is comprised of one or more insulating materials, e.g., silicon nitride, a low-k material, etc. The plan view also depicts (in dashed lines) where a plurality of conductive vias 130A-C (e.g., CA contact structures—the vias will be collectively referenced using the numeral 130) will be formed to contact certain of the source/drain contact structures 120. More specifically, the vias 130A and 130B will be formed on opposite sides of the SDB isolation region 107. Also shown in the plan view in FIG. 4 is the location where another via 132 (e.g., a CB gate contact structure) will be formed to contact the gate structure 108 of gate 5.

The plan view also depicts where a plurality of conductive lines 105A-E (collectively referenced using the numeral 105) will be formed for the product 100 using the methods disclosed herein. As indicated, the line 105A will be conductively coupled to the via 130A; the line 105B will be conductively coupled to the via 130B, the line 105C will be conductively coupled to the via 130C and the line 105E will be conductively coupled to the via 132.

The drawings included herein also include two cross-sectional drawings (“X-X” and “Y-Y”) that are taken where indicated in the plan view (and taken at an earlier stage in the flow than the one illustrated on FIG. 4). More specifically, the cross-sectional view X-X is taken through the gates 106 in a gate-length direction of the transistor devices at a location where the vias 130A, 130B and the lines 105A, 105B will be formed. The cross-sectional view Y-Y is taken through the gates 106 in a gate-length direction of the transistor devices at a location where the via 130C and the lines 105C, 105D will be formed. A cross-sectional view has not been provided through the via 132 and the line 105E. It should be noted that not all aspects of the processing operations shown in cross-sectional views X-X and Y-Y will be reflected in the associated plan view so as to not overly complicate the drawings and to facilitate a better understanding of the subject matter disclosed herein.

The substrate 102 may have a variety of configurations, such as the depicted bulk silicon configuration. The substrate 102 may also have a silicon-on-insulator (SOI) configuration that includes a bulk silicon layer, a buried insulation layer and an active layer, wherein semiconductor devices are formed in and above the active layer. The substrate 102 may be made of silicon or it may be made of materials other than silicon. Thus, the terms “substrate” or “semiconductor substrate” should be understood to cover all semiconducting materials and all forms of such materials. Additionally, various doped regions, e.g., halo implant regions, well regions and the like, are not depicted in the attached drawings.

FIG. 4 depicts the IC product 100 after several process operations were performed. First, as noted above, the fins 103 were formed, and the gates 106 were formed above the fins 103. In the illustrative example depicted herein, the gates 106 of the transistor devices comprise gate structures 108 manufactured using well-known replacement gate manufacturing techniques. Each of the gates 106 includes a schematically depicted final gate structure 108, a gate cap 110 and a sidewall spacer 112. The sidewall spacers 112 and the gate caps 110 may be comprised of a variety of different materials, such as silicon nitride, SiNC, SiN, SiCO, and SiNOC, etc., and they may be made of the same or different materials. Typically, the materials for the gate structures 108 are sequentially formed in gate cavities between the spacers 112 after removal of a sacrificial gate electrode (not shown) and a sacrificial gate insulation layer (not shown). The gate structures 108 are typically comprised of a high-k gate insulation layer (not shown) such as hafnium oxide, a material having a dielectric constant greater than 10, etc., and one or more conductive material layers that function as the gate electrode of the gate structure 108. For example, one or more work-function adjusting metal layers and a bulk conductive material may be deposited to form the gate electrode structure. The gate structures 108 of the gates are formed on a gate pitch 108X, the magnitude of which may vary depending upon the particular application. The gate structures 108 of the gates 106 also define a gate length 108Y (as measured in the current transport direction at the point where the gate structure 108 contacts the substrate 102). The magnitude of the gate length 108Y may also vary depending upon the particular application.

Still referencing FIG. 4, prior to the formation of the final gate structures 108, epi semiconductor material 116 was formed on the exposed portions of the active regions 103 (or fins in the case of a FinFET device), i.e., in the source/drain regions of the devices, by performing an epitaxial growth process. The epi material 116 may be formed to any desired thickness. However, it should be understood that the epi material 116 need not be formed in all applications. Other layers of material, such as contact etch stop layers and the like, are not depicted in the drawing. Also depicted are illustrative source/drain contact structures 120 which typically include a so-called “trench silicide” (TS) structure (not separately shown). As indicated, the upper surface of the source/drain contact structures 120 is typically approximately level with the upper surface of the gate caps 110. The SDB isolation region 107 may be formed before or after the formation of the gate structures 108 for the gates 106 by removing the sacrificial gate structure for gate 3 and thereafter filling the cavity with the insulation material for the SDB isolation structure 107.

Also depicted in FIG. 4 are an etch stop layer 123 (e.g., silicon nitride) and a layer of insulating material 122 (e.g., silicon dioxide) which was blanket deposited across the product 100. An optional CMP process may be performed on the upper surface of the layer of insulating material 122 if desired. The thickness 122X of the layer of insulating material 122 may vary depending upon the particular application. As noted above, the methods and devices disclosed herein may be employed at any level of a multiple-level metallization system of an IC product. In the illustrative example depicted herein, the vias 130 are depicted as being CA contact structures that are conductively coupled to the source/drain contact structures 120, the via 132 is a CB gate contact structure and the lines 105 are part of the M0 metallization layer of the overall metallization system. However, the method disclosed herein may be employed to form vias and metal lines at any level and in any location of the overall metallization system, e.g., the M1/V0 level, the M3/V2 level, the M5/V4 level, etc.

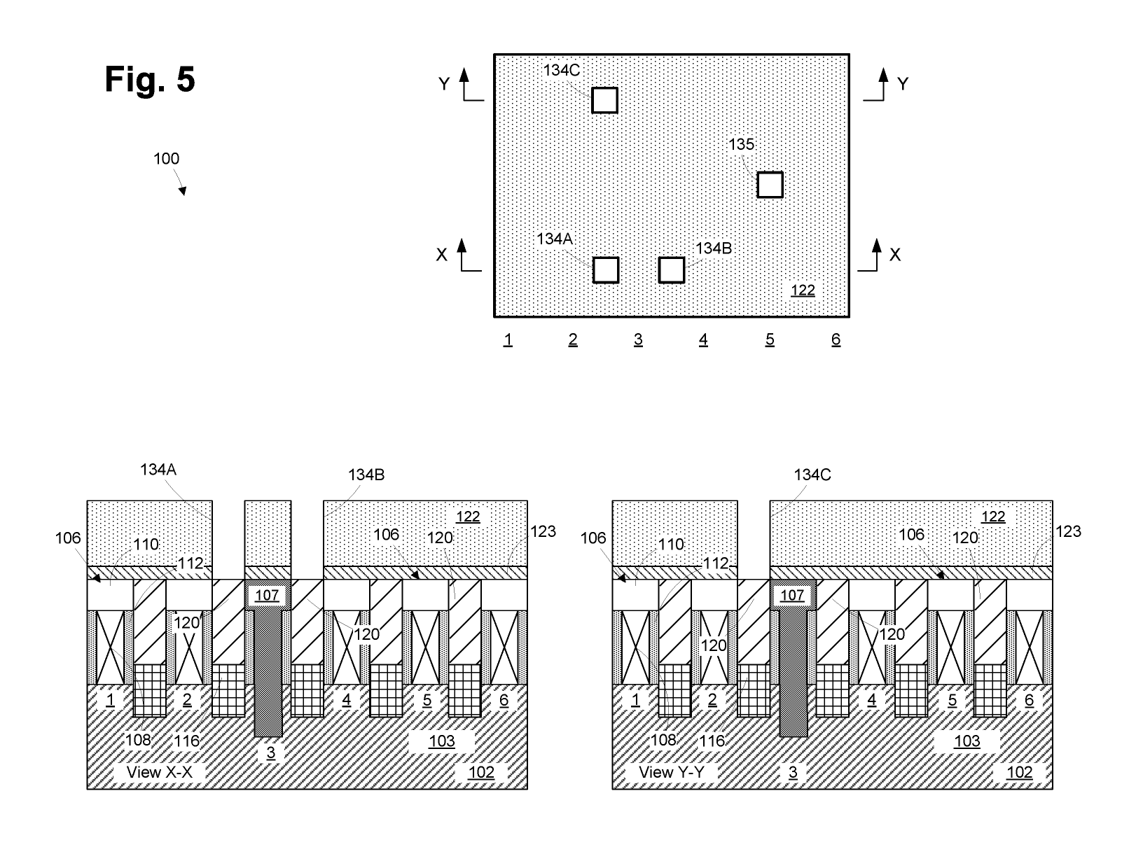

FIG. 5 depicts the IC product 100 after via openings 134A-C (collectively referenced using the numeral 134) and 135 were formed in the layer of insulating material 122. The via openings 134 and 135 were formed by forming a patterned etch mask layer (not shown), e.g., photoresist, OPL, etc., above the product 100, and thereafter performing one or more etching processes through the patterned etch mask layer. FIG. 5 depicts the product 100 after the patterned etch mask layer has been removed. The via openings 134 correspond to the location where the vias 130 A-C will be formed. The via opening 135 (see the plan view) corresponds to the location where the via 132 will be formed. The via openings 134 and 135 may be formed with any desired configuration, e.g., the via openings 134, 135 and the conductive vias that will be formed in these openings, may be in the form of discrete contact elements, i.e., one or more individual contact plugs having a generally square-like shape or cylindrical shape when viewed from above, a line-type feature, etc.

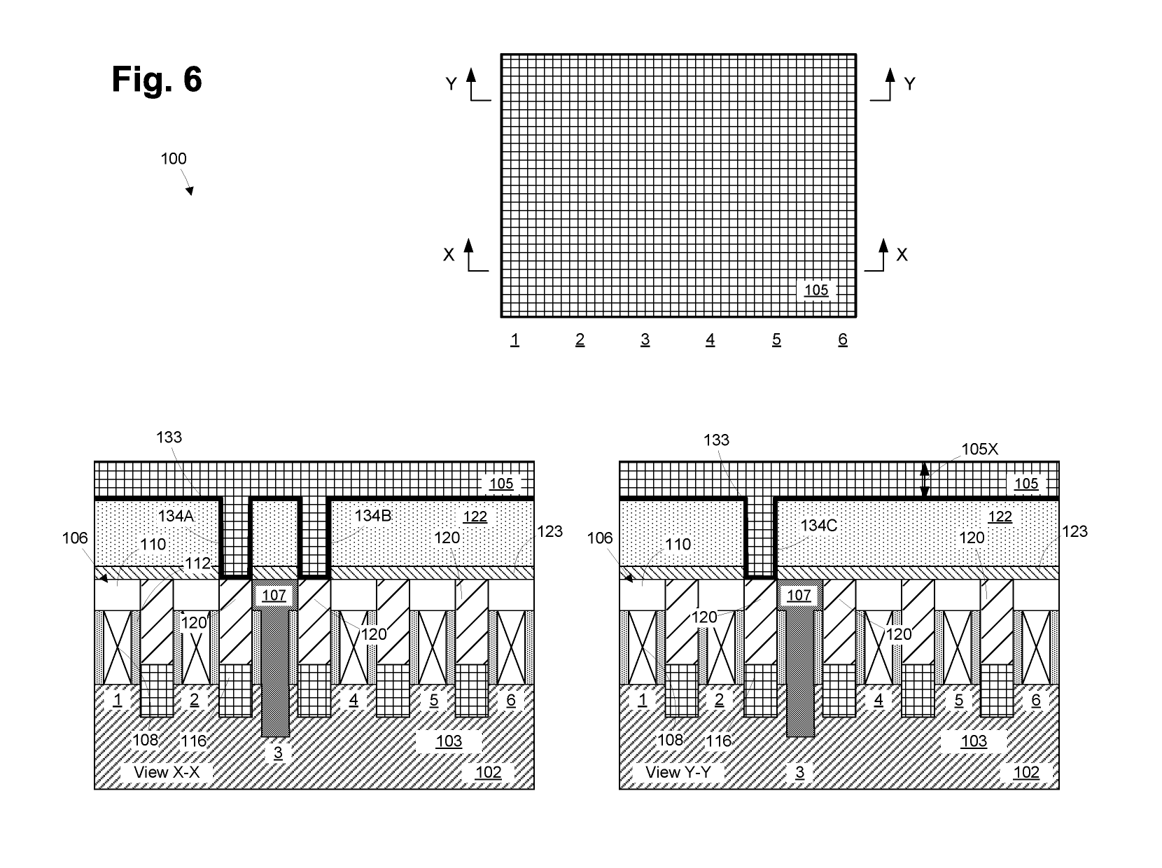

FIG. 6 depicts the product 100 after several process operations were performed. First, a conformal deposition process, e.g., a conformal ALD process, was performed to form a simplistically depicted (and representative) liner layer 133 (e.g., barrier/adhesion layers) across the upper surface of the layer of insulating material 122 and in the openings 134, 135. Thereafter, a blanket deposition process was performed to form a conductive material layer 105 for the metal lines that will be formed on the product 100. As indicated, the conductive material layer 105 was formed such that it overfills the openings 134 and the opening 135 with conductive material. Thus, when it is stated herein and in the appended claims that “conductive material” is deposited so as to form the vias 130, 132 and the metal lines 105 or that the vias 130, 132 and the metal lines 105 comprise a “conductive material,” the term “conductive material” should be understood to represent all forms of conductive materials that are deposited to form the vias 130, 132 and the metal lines 105, i.e., bulk conductive materials as well as one or more liner layers. The vertical thickness 105X of the conductive material layer 105 may vary depending upon the particular application. The conductive material layer 105 maybe comprised of a variety of conductive materials, a metal, a metal-containing material, a metal compound, cobalt, ruthenium, copper, aluminum, tungsten, gold, silver, platinum, iridium, etc.

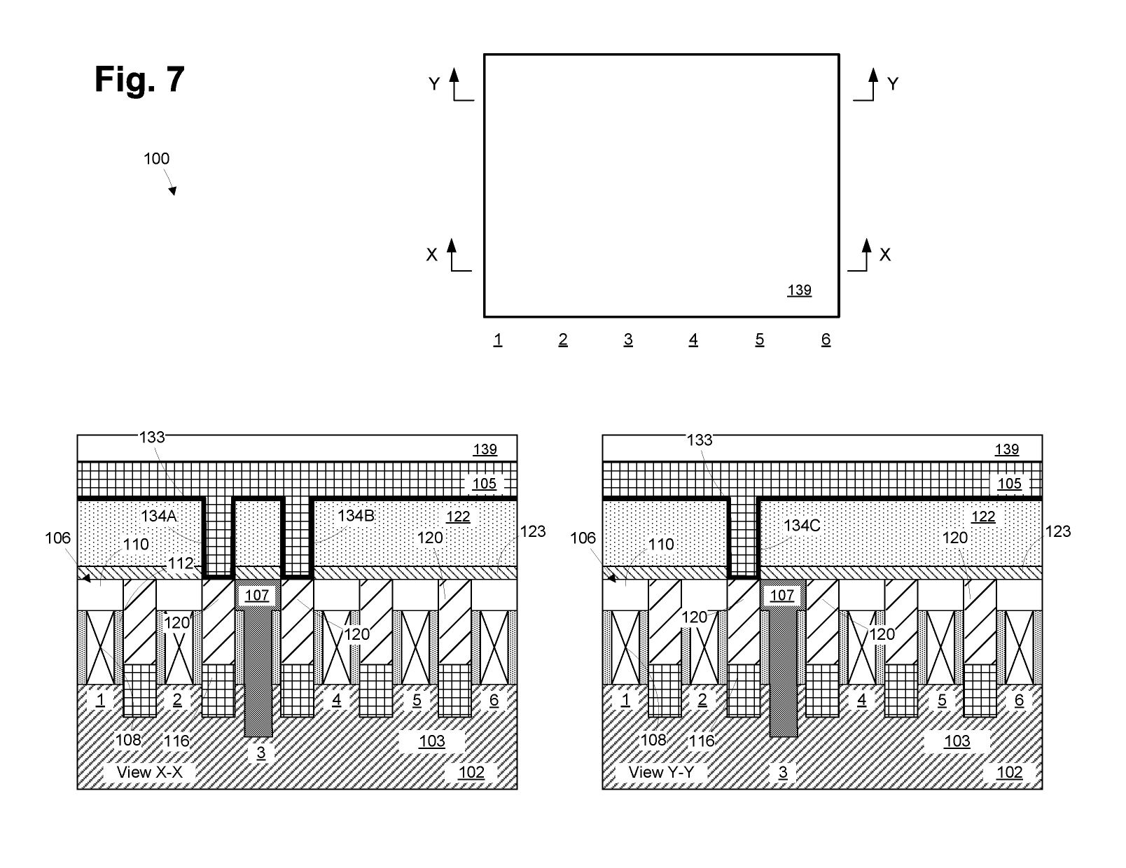

FIG. 7 depicts the product 100 after a line etch mask layer 139 was blanket deposited across the product above the conductive material layer 105. The line etch mask layer 139 maybe comprised of a variety of different materials, e.g., silicon nitride, SiNC, SiN, SiCO, and SiNOC, SiON, TiN, etc., and it may be formed to any desired thickness.

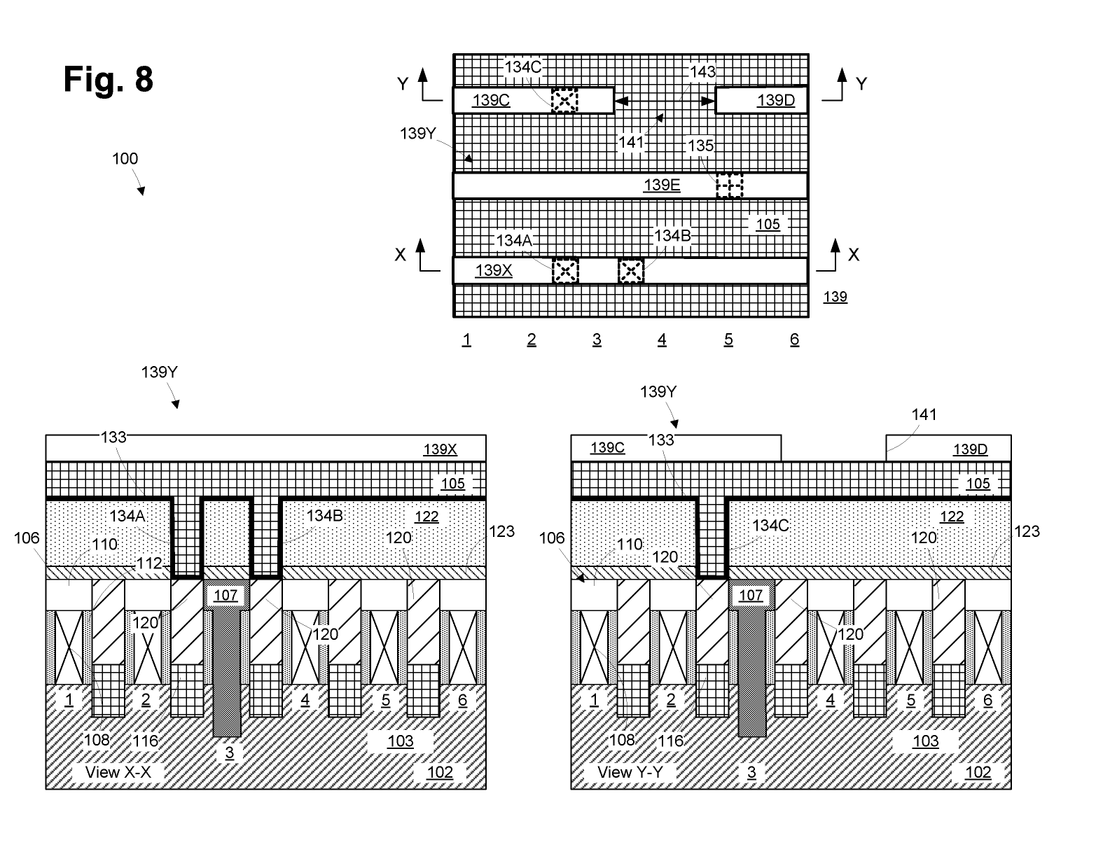

FIG. 8 depicts the product 100 after several process operations were performed. First, a first patterned etch mask (not shown), e.g., photoresist, OPL, etc., was formed above the line etch mask layer 139. Thereafter, one or more first etching processes were performed through the first patterned etch mask to remove exposed portions of the line etch mask layer 139. This first etching process defines a partially patterned line etch mask layer 139Y that contains a portion of the final pattern that will be defined in the conductive material layer 105, as described more fully below. More specifically, the partially patterned line etch mask layer 139Y comprises line features 139X, 139C, 139D and 139E. The features 139C, 139D and 139E correspond to the metal lines 105C, 105D and 105E (see FIG. 4) that will be formed in the conductive material layer 105. The line feature 139X is, at this point, a continuous line feature that will eventually be further patterned as described more fully below. Note the partially patterned line etch mask layer 139Y comprises an opening 141 that defines a relatively large (e.g., 45-100 nm or greater) tip-to-tip spacing 143 between the features 139C and 139D.

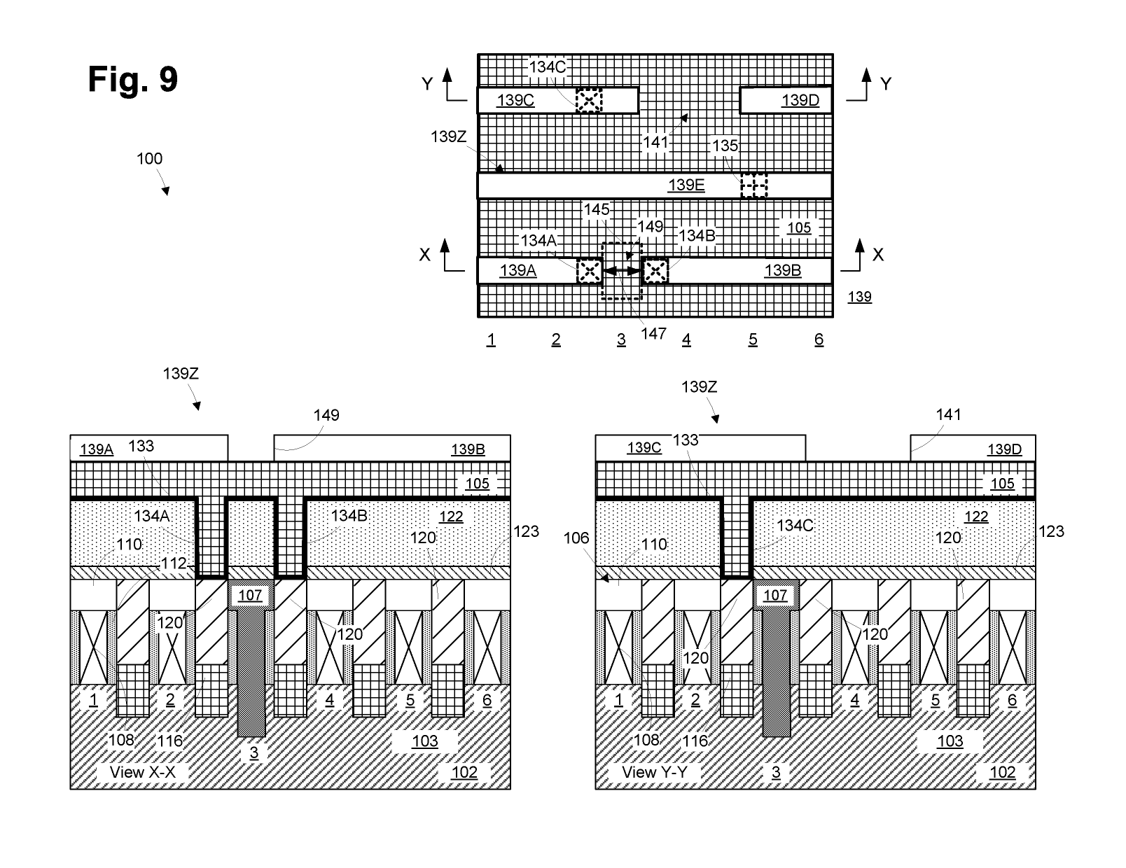

FIG. 9 depicts the product 100 after several process operations were performed.

First, the first patterned etch mask was removed. Then a second patterned etch mask (not shown), e.g., photoresist, OPL, etc., was formed above the partially patterned line etch mask layer 139Y. With reference to the plan view, the second patterned etch mask comprises an opening 145 (depicted in dashed lines) that exposes a portion of the feature 139X (see FIG. 8) between the openings 134A and 134B. The opening 145 in the second patterned etch mask may be formed to relatively precise dimensions since it is a relatively isolated feature that is easier to print to the desired dimensions using photolithographic techniques due to the absence of nearby features that can make printing closely spaced features more difficult. Thereafter, one or more second etching processes were performed through the second patterned etch mask to remove exposed portions of the feature 139X of the partially patterned line etch mask layer 139Y. This second etching process defines a fully patterned line etch mask layer 139Z that contains the final pattern that will be defined in the conductive material layer 105, as described more fully below. As depicted, this second etching process cuts the previous continuous line feature 139X (see FIG. 8) into features 139A and 139B. The features 139A and 139B correspond to metal lines 105A and 105B (see FIG. 4). Note the fully patterned line etch mask layer 139Z now comprises another opening 149 that defines a relatively small (e.g., 20-50 nm) tip-to-tip spacing 147 between the features 139A and 139B. In some applications, the spacing 147 may correspond to the spacing between the vias 130A and 130B that will be formed in the openings 134A, 134B, respectively. In one particular example, the spacing 147 may correspond approximately to the gate length 108Y (see FIG. 4) of the gate structures 108 of the gates 106. In other cases, the spacing 147 may correspond to at least 75% of the gate pitch 108X (see FIG. 4), i.e., the resulting metal lines 105A, 105B will enclose the underlying vias 130A, 130B by a relatively small distance. Note the order of the first and second etching processes performed on the etch mask layer 139 described above may be reversed if desired.

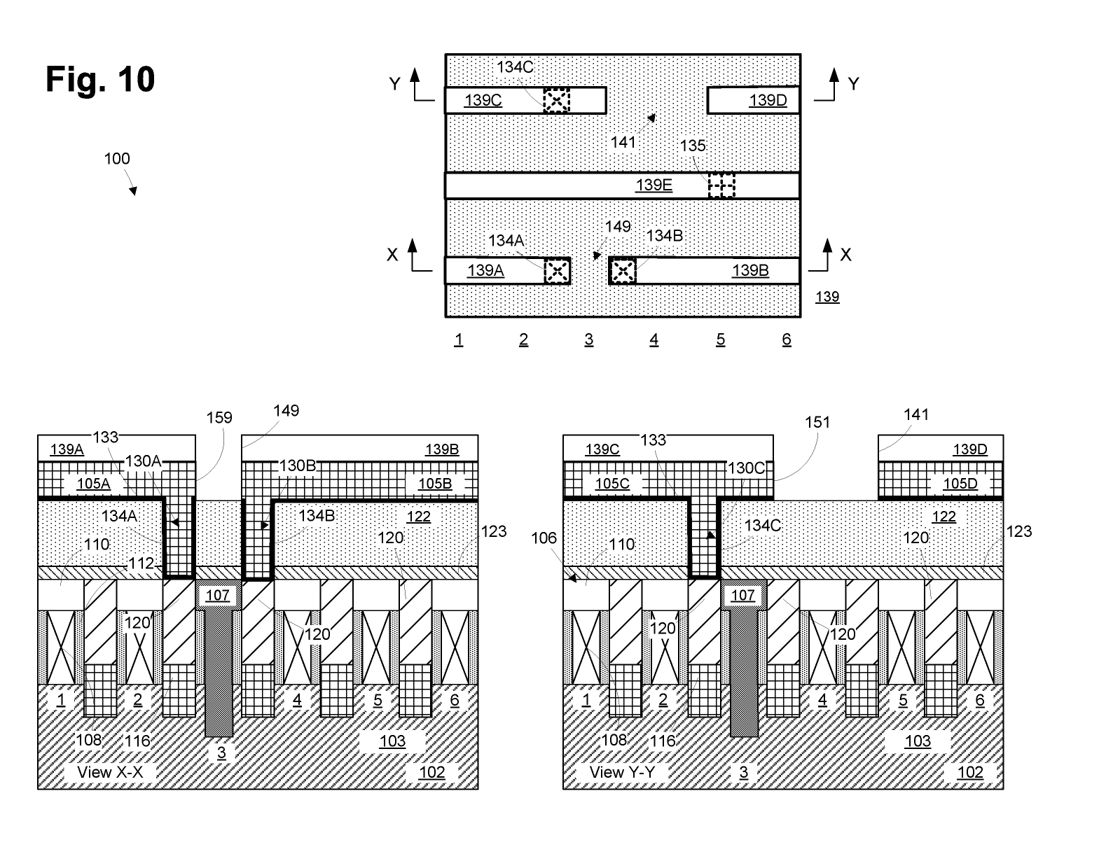

FIG. 10 depicts the product 100 after several process operations were performed. First, the second patterned etch mask was removed. Thereafter, one or more third etching processes were performed through the fully patterned line etch mask layer 139Z to remove exposed portions of the conductive material layer 105 and thereafter the liner layer 133. This third etching process results in the formation of the conductive lines 105A-E, the vias 130A-C (in the openings 134A-C, respectively) and the via 132 (in the opening 135). The third etching processes defines openings 151 and 159 in the conductive material layer 105 that correspond to the openings 141 and 149 in the fully patterned line etch mask layer 139Z. Note that the conductive via 130A is conductively coupled to a first source/drain region 120 and the second conductive via 130B is conductively coupled to a second source/drain region 120 that are positioned proximate the opposite sides of the SDB structure 107, the first and second source/drain regions are part of first and second transistors, respectively, that, in one embodiment, are transistors for different circuits formed above the substrate.

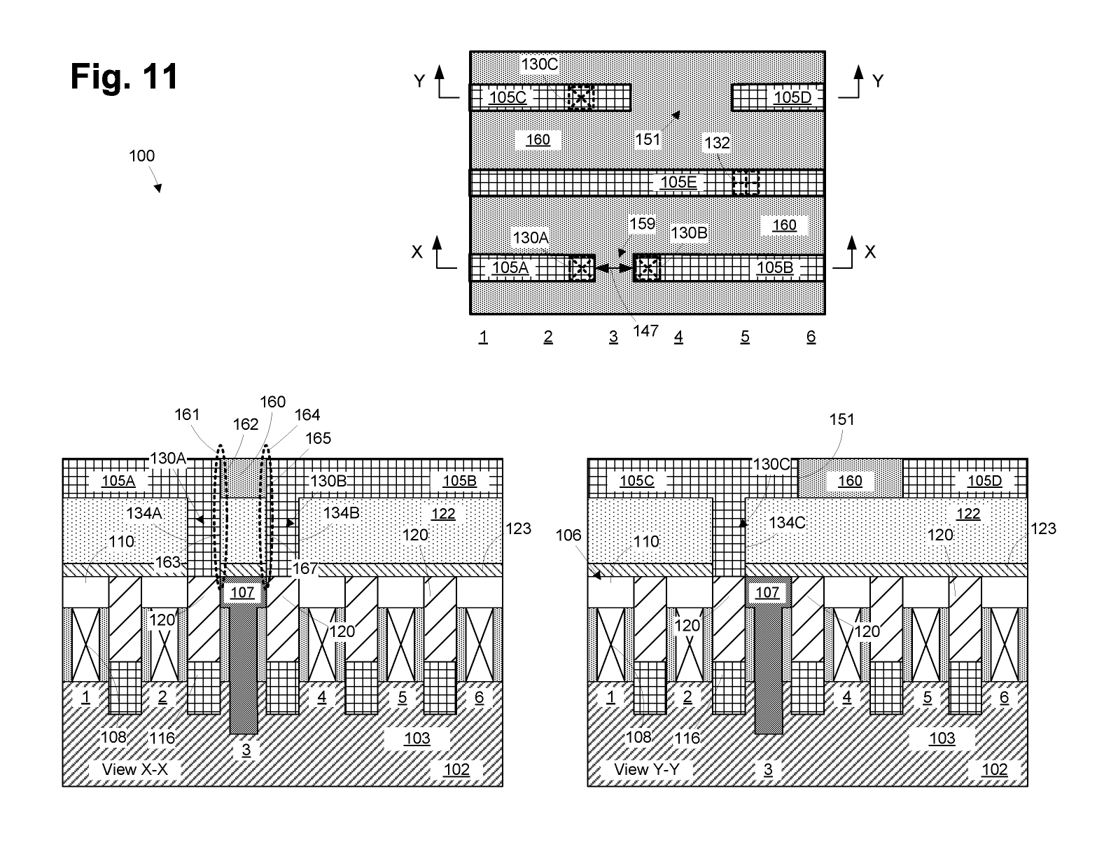

FIG. 11 depicts the product 100 after several process operations were performed. Note that the liner layer 133 has been omitted from FIG. 11 so as not to overly complicate the drawing. First, the fully patterned line etch mask layer 139Z was removed. Thereafter, a layer of insulating material 160, e.g., a low-k insulating material, silicon dioxide, etc., was deposited on the product so as to overfill the spaces between the lines 105 and in the openings 151 and 159. Next, a CMP process was performed to remove excess amounts of the insulating material 160 positioned above the upper surface of the metal lines 105. Note that, in the illustrative example depicted herein where the vias 130A, 130B are CA contact structures, the methods disclosed provide a means to form conductive lines (105A, 105B) with very small tip-to-tip spacing 147 between the associated metal lines 105A, 105B and similar if not identical spacing between the vias 130A, 130B. As noted above, in some applications, the spacing 147 between the lines 105A and 105B (and the vias 130A and 130B) may correspond approximately to the gate length 108Y (see FIG. 4) of the gate structures 108 of the gates 106 or at least about 75% of the gate pitch 108X (see FIG. 4) (with the associated metal line enclosure of the underlying via). Additionally, in the depicted example, the features 139A and 139B in the fully patterned line etch mask layer 139Z were formed by first forming a substantially continuous line-type feature 139X (see FIG. 8) in the partially patterned line etch mask layer 139Y and thereafter cutting (by etching—see FIG. 9) the continuous feature 139X. This permits the tip-to-tip spacing 147 to be reliably and repeatedly formed to very small dimensions as opposed to trying to directly pattern the separate features 139A and 139B (by etching) with a similar tip-to-tip spacing 147, due to inherent limitations associated with existing photolithography tools and techniques. Lastly, unlike the prior art dual damascene process disclosed in the background section of this application, wherein the conductive lines are deposited in previously formed trenches in a layer of insulating material, the conductive lines 105 disclosed herein are formed by patterning the conductive material layer 105 using the fully patterned line etch mask layer 139Z. This is particularly advantageous where an edge of the via 130 is positioned very close to the line end of the associated metal line 105 as the conformal liner layers (barrier layers, etc.) do not need to be formed in a relatively deep opening (with a high aspect ratio) having a depth corresponding approximately to the vertical height of the via and the vertical thickness of the metal line. Rather, using the present methodologies, the conformal liner layers are formed in only the via openings 134 and 135 that have a much smaller aspect ratio and on the upper surface of the layer of insulating material 122. Thus, the various methodologies disclosed herein may lead to fewer manufacturing errors and increased product yields.

The dashed line regions 161 and 164 in the view X-X in FIG. 11 depict the unique relationship between the ends of the lines 105 and the underlying vias 130, 132 that may be achieved using the novel methods disclosed herein. More specifically, the dashed line regions 161 and 164 depict the situation where the lateral dimension of the opening 159 (in the same direction as that of the dimension 147) corresponds approximately to the gate length 108Y of the gate structures 108 of the gates 106. With reference to the dashed line region 161, the end 162 of the line 105A is fully aligned with edge 163 of the via 130A, i.e., there is essentially zero enclosure or overlap. Similarly, as shown in the dashed line region 164, the end 165 of the line 105B is fully aligned with edge 167 of the via 130B, i.e., there is essentially zero enclosure or overlap. Thus, the term “fully aligned” when used in the appended claims should be understood to cover the situation shown in the dashed line regions 161 and 164 shown in FIG. 11. Thus, the present methodologies present means by which further scaling of IC products can be achieved in that the methods disclosed herein allow for very small tip-to-tip spacing between metal lines in metallization systems, thereby permitting increased packing densities. In another example, the ends of the conductive lines may extend to the edge of their associated respective conductive via by a distance of 5 nm or less.

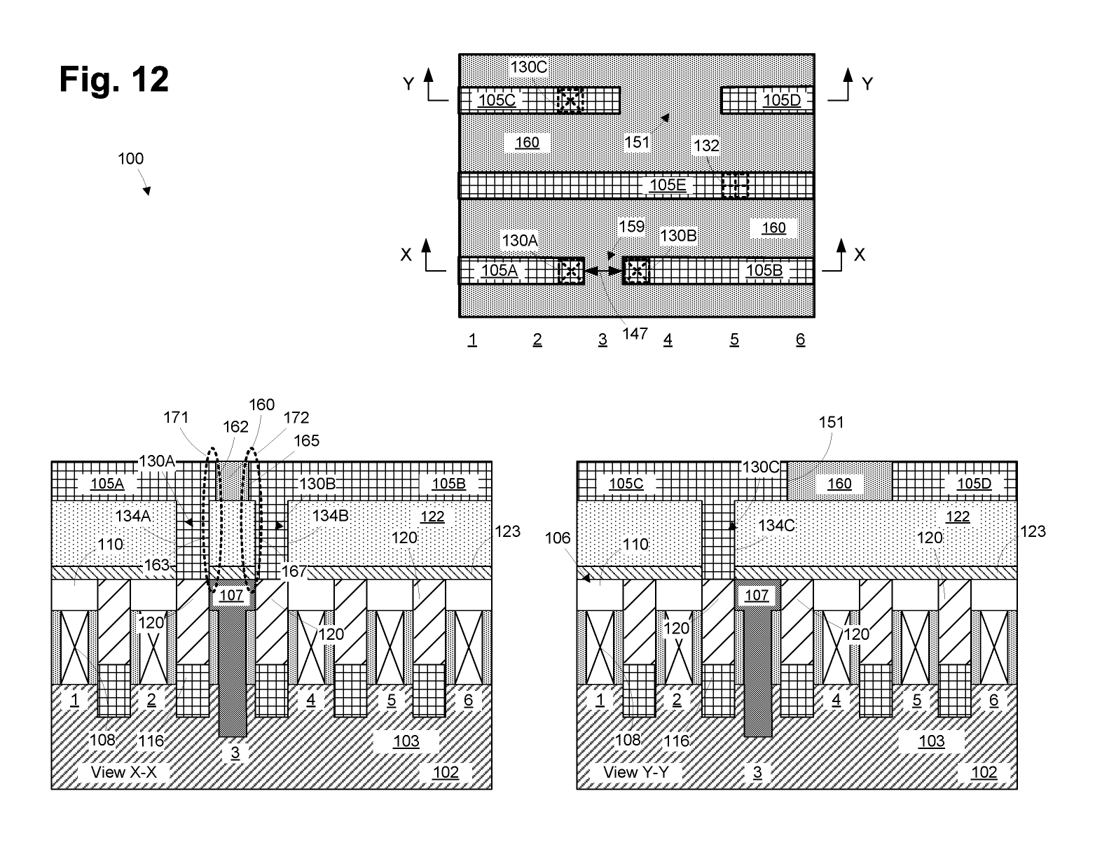

FIG. 12 depicts an embodiment wherein the metal lines 105 enclose the underlying conductive vias 130. Note that the liner layer 133 has been omitted from FIG. 12 so as not to overly complicate the drawing. In such an embodiment, the lateral dimension of the opening 159 (in the same direction as that of the dimension 147) may be at least about 75% of the gate pitch 108X (see FIG. 4). More specifically, in this embodiment, the end 162 of the line 105A extends slightly beyond the edge 163 of the via 130A, i.e., there is a small amount of line enclosure or overlap, i.e., the end 162 is vertically offset with the edge 163. Similarly, the end 165 of the line 105B is vertically offset from the edge 167 of the via 130B by a similar amount. Thus, the term “vertically offset” when used in the appended claims should be understood to cover the situation shown in the dashed line regions 171 and 172 shown in FIG. 12. The term “substantially aligned” when used in the appended claims to describe the relationship between the end of the metal line and any underlying conductive via should be understood to cover the situation depicted in both FIG. 11 (essentially no line end enclosure) and FIG. 12 (limited line end enclosure).

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
forming first and second via openings in a layer of insulating material;
forming conductive material for first and second conductive vias in said first and second via openings and across substantially an entirety of an upper surface of said layer of insulating material;
forming a patterned line etch mask layer above said conductive material, said patterned line etch mask layer having a first feature corresponding to a first conductive line that will be conductively coupled to said first conductive via and a second feature corresponding to a second conductive line that will be conductively coupled to said second conductive via; and
performing at least one etching process through said patterned line etch mask layer to etch said conductive material and form said first conductive line and said second conductive line, wherein said first and second conductive lines are arranged in a tip-to-tip configuration and wherein a first edge of said first conductive via is substantially aligned with a first end of said first conductive line and a second edge of said second conductive via is substantially aligned with a second end of said second conductive line.

2. The method of claim 1, wherein said first edge is fully aligned with said first end and said second edge is fully aligned with said second end.

3. The method of claim 1, wherein said first edge is vertically offset from said first end and said second edge is vertically offset from said second end.

4. The method of claim 1, wherein forming said patterned line etch mask layer comprises:
depositing a layer of etch mask material above said conductive material;
performing a first patterning process on said layer of etch mask material to form a partially patterned line etch mask layer that comprises a continuous line-type feature that is positioned above both of said first and second via openings and above a lateral space between said first and second via openings; and
performing a second patterning process on said partially patterned line etch mask layer to cut said continuous line-type feature into said first feature and said second feature and form said patterned line etch mask layer, wherein an opening in said patterned line etch mask layer between a first end of said first feature and a second end of said second feature is positioned above at least a portion of said lateral space between said first and second via openings.

5. The method of claim 4, wherein a distance between said first end of said first feature and said second end of said second feature is approximately the same as said lateral space between said first and second via openings.

6. The method of claim 1, wherein a first lateral distance between said first edge of said first conductive line and said second end of said second conductive line is substantially equal to a second lateral distance between said first edge of said first conductive via and said second edge of said second conductive via.

7. The method of claim 1, wherein a first lateral distance between said first edge of said first conductive line and said second end of said second conductive line is less than a second lateral distance between said first edge of said first conductive via and said second edge of said second conductive via.

8. The method of claim 1, wherein said conductive material comprises at least one conformal liner layer and a blanket-deposited layer comprising a metal.

9. The method of claim 1, wherein, prior to forming said first and second via openings, the method further comprises forming a plurality of transistor devices above a semiconductor substrate, said transistor devices being formed with a gate pitch of 45 nm or less, wherein said layer of insulating material is formed above said plurality of transistor devices, and wherein said first end of said first conductive line extends past said first edge of said first conductive via by a distance of 5 nm or less and said second end of said second conductive line extends past said second edge of said second conductive via by a distance of 5 nm or less.

10. The method of claim 1, wherein said first and second conductive vias are device level contacts and said first and second conductive lines are part of an M0 metallization layer of an integrated circuit product.

11. The method of claim 1, wherein, prior to forming said first and second via openings, the method further comprises forming a single diffusion break structure that extends at least partially into a semiconductor substrate, said single diffusion break structure being positioned between first and second source/drain regions positioned proximate opposite sides of said single diffusion break structure, wherein said first and second source/drain regions are part of first and second transistors, respectively, and wherein said first conductive via is conductively coupled to said first source/drain region and said second conductive via is conductively coupled to said second source/drain region.

12. The method of claim 1, wherein forming said patterned line etch mask layer comprises:
depositing a layer of etch mask material above said conductive material;
performing a first patterning process on said layer of etch mask material to form a partially patterned line etch mask layer, said partially patterned line etch mask layer comprising an opening that is positioned above at least a portion of a lateral space between said first and second via openings; and
performing a second patterning process on said partially patterned line etch mask layer to form said first feature and said second feature of said patterned line etch mask layer, wherein a line opening between a first end of said first feature and a second end of said second feature is positioned above at least a portion of said lateral space between said first and second via openings.

13. The method of claim 1, wherein a first lateral distance between said first edge of said first conductive line and said second end of said second conductive line is equal to at least 75 percent of a gate pitch of a plurality of transistor devices positioned below said first and second conductive lines.

14. A method, comprising:
forming first and second via openings in a layer of insulating material;
forming conductive material for first and second conductive vias in said first and second via openings and across substantially an entirety of an upper surface of said layer of insulating material;
performing at least two patterning process operations to form a patterned line etch mask layer above said conductive material, said patterned line etch mask having a first feature corresponding to a first conductive line that will be conductively coupled to said first conductive via and a second feature corresponding to a second conductive line that will be conductively coupled to said second conductive via; and
performing at least one etching process through said patterned line etch mask layer to etch said conductive material and form said first conductive line and said second conductive line, wherein said first and second conductive lines are arranged in a tip-to-tip configuration and wherein an end-to-end spacing between a first end of said first conductive line and a second end of said second conductive line is equal to at least 75 percent of a gate pitch of a plurality of transistor devices positioned below said first and second conductive lines.

15. The method of claim 14, wherein said end-to-end spacing is approximately equal to said gate pitch.

16. An integrated circuit product, comprising:
first and second conductive vias positioned in a layer of insulating material;
a first conductive line that is conductively coupled to said first conductive via; and
a second conductive line that is conductively coupled to said second conductive via, wherein said first and second conductive lines are arranged in a tip-to-tip configuration and wherein a first edge of said first conductive via is substantially aligned with a first end of said first conductive line and a second edge of said second conductive via is substantially aligned with a second end of said second conductive line.

17. The integrated circuit product of claim 16, wherein said first edge is fully aligned with said first end and said second edge is fully aligned with said second end.

18. The integrated circuit product of claim 16, wherein said first edge is vertically offset from said first end and said second edge is vertically offset from said second end.

19. The integrated circuit product of claim 16, wherein a spacing between said first end and said second end is approximately equal to at least 75 percent of a gate pitch of a plurality of transistor devices positioned below said first and second conductive lines.
